(19) United States
(12) Patent Application Publication
(10) Pub. No.: US 2008/0238517 A1
(43) Pub. Date: Oct. 2, 2008

(54) Oscillator Circuit and Semiconductor Device

(75) Inventors: Hideo NUNOKAWA, Kawasaki (JP); Kazuhiro Mitsuda, Kawasaki (JP)

Correspondence Address: ARENT FOX LLP, 1050 CONNECTICUT AVENUE, N.W., SUITE 400, WASHINGTON, DC, 20036, US

(73) Assignee: Fujitsu Limited, Kawasaki (JP)

(21) Appl. No.: 12/056,041

(22) Filed: Mar. 26, 2008

(30) Foreign Application Priority Data
Mar. 26, 2007 (JP) 2007-080161

(51) Int. Cl. H03K 3/02

(52) U.S. Cl. 327/291; 331/143

(57) ABSTRACT

An oscillator circuit includes a capacitance element; an inverter outputting an inverted voltage at a first terminal of the capacitance element; a voltage source including a resistor and an NMOS transistor connected in series between a first high-potential power supply and a ground power supply and outputting a voltage from a node to which the resistor and the NMOS transistor are connected; a switch circuit connecting a second terminal of the capacitance element to the voltage source or the ground power supply in accordance with the voltage output from the inverter; and a constant-current source connected to a second high-potential power supply and allowing, regardless of changes in the voltage and temperature of the second high-potential power supply within certain ranges, flow of a constant current into or out of the first terminal of the capacitance element in accordance with the voltage output from the inverter.

### TECHNICAL FILED

This is relates to oscillator circuits and semiconductor device includes the oscillator circuits.

### BACKGROUND

In a semiconductor device including an oscillator circuit, it is desirable that a clock frequency supplied from the oscillator circuit should not depend on changes in the power supply voltage and temperature. If the oscillation frequency greatly changes in response to changes in the power supply voltage and temperature, the operation timing of circuits which are in the semiconductor device and which operate in response to the clock greatly changes, and signals cannot be transferred between the circuits.

As the oscillator circuit, a so-called CR oscillator circuit that oscillates using charging and discharging characteristics of a capacitance element and a resistance element is used. To reduce the dependence of the clock frequency supplied from the oscillator circuit on the power supply voltage and temperature, the following oscillator circuit is proposed (e.g., see Japanese Laid-open Patent Application Publication No. 2005-217762).

FIG. 6 is a circuit diagram showing an oscillator circuit described in Japanese Unexamined Patent Application Publication No. 2005-217762. Referring to FIG. 6, the oscillator circuit includes a capacitance element 10, an inverter circuit 8 for inverting a voltage at a first terminal of two terminals of the capacitance element 10 and outputting the inverted voltage, a constant-current generating circuit 1 for allowing the flow of a constant current regardless of changes in the power supply voltage and temperature into the first terminal of the capacitance element 10 or out of the first terminal of the capacitance element 10 in accordance with the voltage output from the inverter circuit 8, a constant voltage source 35 for outputting a constant voltage regardless of changes in the power supply voltage and temperature, and a switch circuit 15 for connecting a second terminal of the capacitance element 10 to the first of the constant voltage source 35 and a ground power supply VSS3 in accordance with the voltage output from the inverter circuit 8.

In accordance with the flow of current from the constant-current generating circuit 1, the potential at the first terminal of the capacitance element 10 increases and reaches a threshold voltage of the inverter circuit 8. Accordingly, a voltage is applied from the constant voltage source 35 to the second terminal of the capacitance element 10, and the potential at the first terminal of the capacitance element 10 increases to a predetermined potential. Thereafter, the constant-current generating circuit 1 allows the current to flow out, and the potential at the first terminal of the capacitance element 10 decreases and reaches the threshold voltage of the inverter circuit 8. Accordingly, a ground voltage is applied from the ground power supply VSS3 to the second terminal of the capacitance element 10, and the potential at the first terminal of the capacitance element 10 decreases to a predetermined potential.

With the constant-current generating circuit 1, the current that flows into and out of the capacitance element 10 is constant regardless of changes in the power supply voltage and temperature.

Since the voltage generated by the constant voltage source 35 is constant regardless of changes in the power supply voltage and temperature, the upper limit of voltage that appears at the first terminal of the capacitance element 10 is constant.

Therefore, charging and discharging of the capacitance element 10 is repeated in constant time intervals, and the oscillator circuit supplies a clock with a clock frequency that does not depend on changes in the power supply voltage and temperature.

FIG. 7 is a circuit diagram showing the constant voltage source described in Japanese Laid-open Patent Application Publication No. 2005-217762. Referring to FIG. 7, the constant voltage source 35 includes a current mirror circuit that generates, for example, a constant current I11 and that includes PMOS transistors M31 and M32, NMOS transistors M33 and M34, bipolar transistors Q11 and Q12, and a resistor R12, and a voltage dividing circuit that performs temperature compensation and that includes an NMOS transistor M35, a resistor R13, and a bipolar transistor Q13. The constant voltage source 35 includes many semiconductor devices.

Many semiconductor devices including MOS transistors are necessary for supplying a clock with a stable clock frequency using the constant voltage source that is included in the foregoing oscillator circuit and that outputs a constant voltage regardless of changes in the power supply voltage and temperature. As a result, the circuits included in the oscillator circuit occupy a large layout area.

### SUMMARY

According to an aspect of the embodiments, an oscillator circuit includes a capacitance element; an inverter for inverting a voltage at a first terminal of the capacitance element and outputting the inverted voltage; a voltage source including a resistor and an NMOS transistor that are connected in series between the first high-potential power supply and the ground power supply, the voltage source outputting a voltage from a node to which the resistor and the NMOS transistor are connected; a switch circuit for connecting a second terminal of the capacitance element to one of the voltage source and the ground power supply in accordance with the voltage output from the inverter; and a constant-current source for allowing flow of a constant current into the first terminal of the capacitance element or flow of a constant current out of the first terminal of the capacitance element in accordance with the voltage output from the inverter, regardless of changes in the voltage and temperature of the second high-potential power supply within certain ranges, the constant-current source being connected to the second high-potential power supply.

### BRIEF DESCRIPTION OF THE DRAWINGS

FIG. 1 is a circuit diagram showing an oscillator circuit according to a first embodiment;

FIG. 2 is a waveform diagram showing changes in the potential at nodes NA20, NB21, and NC22 of the oscillator circuit shown in FIG. 1;

FIG. 3A is a graph showing changes in the potential level of a VINV signal in response to changes in the voltage of a high-potential power supply VDP17 of a VINV-signal generating circuit 18;

FIG. 3B is a graph showing changes in the frequency of a clock output from the oscillator circuit according to the first embodiment in accordance with the potential of a VINV signal 16;

FIG. 4 is a circuit diagram showing an oscillator circuit according to a second embodiment;

FIG. 5 is a diagram for describing a constant-current generating circuit 1;

FIG. 6 is a circuit diagram of an oscillator circuit described in Japanese Unexamined Patent Application Publication No. 2005-217762; and

FIG. 7 is a circuit diagram of a constant voltage circuit described in Japanese Unexamined Patent Application Publication No. 2005-217762.

### DESCRIPTION OF THE PREFERRED EMBODIMENTS

A first embodiment and a second embodiment will be described.

### First Embodiment

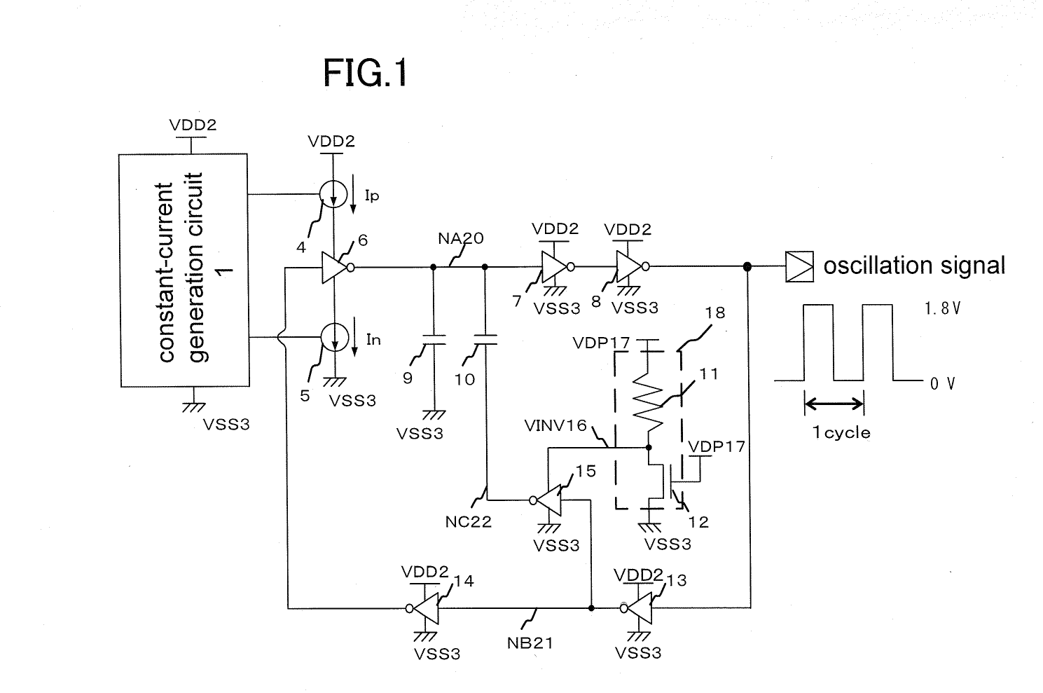

A first embodiment relates to an oscillator circuit that generates a power supply voltage, which is to be connected to a first terminal of a capacitance element that determines an oscillation cycle based on charging and discharging, using a resistor and the ON-resistance of a MOS transistor. The first embodiment will be described using FIGS. 1, 2, 3A, 3B, and 5.

FIG. 1 is a circuit diagram showing an oscillator circuit according to the first embodiment. FIG. 1 shows a constant-current generating circuit 1, a high-potential power supply VDD2, a low-potential power supply VSS3, a current control circuit 4, a current control circuit 5, a switch circuit 6, an inverter circuit 7, an inverter circuit 8, a capacitance element 9, a capacitance element 10, a resistor 11, an NMOS transistor 12, an inverter circuit 13, an inverter circuit 14, a switch circuit 15, a VINV signal 16, a high-potential power supply VDP17, a VINV-signal generating circuit 18, a node NA20, a node NB21, and a node NC22.

### Structure of Oscillator Circuit of First Embodiment

The high-potential power supply VDD2 is a power supply that supplies a high potential to the oscillator circuit of the first embodiment. The low-potential power supply VSS3 is a power supply that supplies a low potential, such as a ground potential, to the oscillator circuit of the first embodiment.

The current control circuit 4 is a current control circuit that maintains a constant current Ip flowing between the high-potential power supply VDD2 and the switch circuit 6. The current control circuit 5 is a current control circuit that maintains a constant current In flowing between the low-potential power supply VSS3 and the switch circuit 6.

The constant-current generating circuit 1 controls the current control circuit 4 interposed between the high-potential power supply VDD2 and the switch circuit 6 and allows the flow of the constant current Ip. Also, the constant-current generating circuit 1 controls the current control circuit 5 interposed between the low-potential power supply VSS3 and the switch circuit 6 and allows the flow of the constant current In. A detailed description of the constant-current generating circuit 1 will be given later. As will be described later, the current control circuit 4 is a PMOS transistor, and the current control circuit 5 is an NMOS transistor.

In accordance with the logic of an input logic signal received at an input terminal of the switch circuit 6, the switch circuit 6 allows the flow of the constant current Ip from the high-potential power supply VDD2 to the capacitance elements 9 and 10 or allows the flow of the constant current In out of the capacitance elements 9 and 10. Therefore, it is possible to assume that the switch circuit 6 includes, for example, an inverter circuit. An inverter circuit includes a pair of a PMOS transistor and an NMOS transistor, that is, includes an input terminal to which a gate electrode of the PMOS transistor and a gate electrode of the NMOS transistor are commonly connected and an output terminal to which a drain electrode of the PMOS transistor and a drain electrode of the NMOS transistor are commonly connected.

The inverter circuit 7, the inverter circuit 8, the inverter circuit 13, and the inverter circuit 14 are inverter circuits that operate on potentials supplied from the high-potential power supply VDD2 and the low-potential power supply VSS3.

An input terminal of the inverter circuit 7 is connected to an output terminal of the switch circuit 6 and to a first terminal of the capacitance elements 9 and 10. An output terminal of the inverter circuit 7 is connected to an input terminal of the inverter circuit 8.

The output terminal of the inverter circuit 8 is connected to an input terminal of the inverter circuit 13. An output terminal of the inverter circuit 13 is connected to an input terminal of the switch circuit 15 and to an input terminal of the inverter circuit 14. An output terminal of the inverter circuit 14 is connected to an input terminal of the switch circuit 6.

An output terminal of the oscillator circuit of the first embodiment that outputs an oscillation signal is connected to the output terminal of the inverter circuit 8.

The switch circuit 15 is an inverter circuit that operates on the VINV signal 16 and a potential supplied from the low-potential power supply VSS3. In response to a signal output from an output terminal of the inverter circuit 8, the switch circuit 15 plays the role of a switch that outputs the VINV signal 16 or the ground potential supplied from the low-potential power supply VSS3 to a second terminal of the capacitance element 10.

The capacitance element 9 is a capacitance element whose first terminal is connected to the output terminal of the switch circuit 6, the input terminal of the inverter circuit 7, and the first terminal of the capacitance element 10. A second terminal of the capacitance element 9 is connected to the low-potential power supply VSS3.

The capacitance element 10 is a capacitance element whose first terminal is connected to the output terminal of the switch circuit 6, the input terminal of the inverter circuit 7, and the first terminal of the capacitance element 9. A second terminal of the capacitance element 10 is connected to an output terminal of the switch circuit 15.

The VINV-signal generating circuit 18 includes the resistor 11 and the NMOS transistor 12, which are connected in series between the high-potential power supply VDP17 and the low-potential power supply VSS3. The resistor 11 is connected to the high-potential power supply VDP17 and a drain of the NMOS transistor 12. A source of the NMOS transistor 12 is connected to the low-potential power supply VSS3, and a gate of the NMOS transistor 12 is connected to the high-potential power supply VDP17. The VINV signal 16 is output from an output terminal connected to the node to which the resistor 11 and the drain of the NMOS transistor 12 are connected, and the potential of the VINV signal 16 is VINV.

The node NA20 is a node to which the output terminal of the switch circuit 6, the first terminal of the capacitance element 9, the first terminal of the capacitance element 10, and the input terminal of the inverter circuit 7 are connected.

The node NB21 is a node to which the output terminal of the inverter circuit 13, the input terminal of the inverter circuit 14, and the input terminal of the switch circuit 15 are connected.

The node NC22 is a node to which the second terminal of the capacitance element 10 and the output terminal of the switch circuit 15 are connected.

### Operation of Oscillator Circuit of First Embodiment

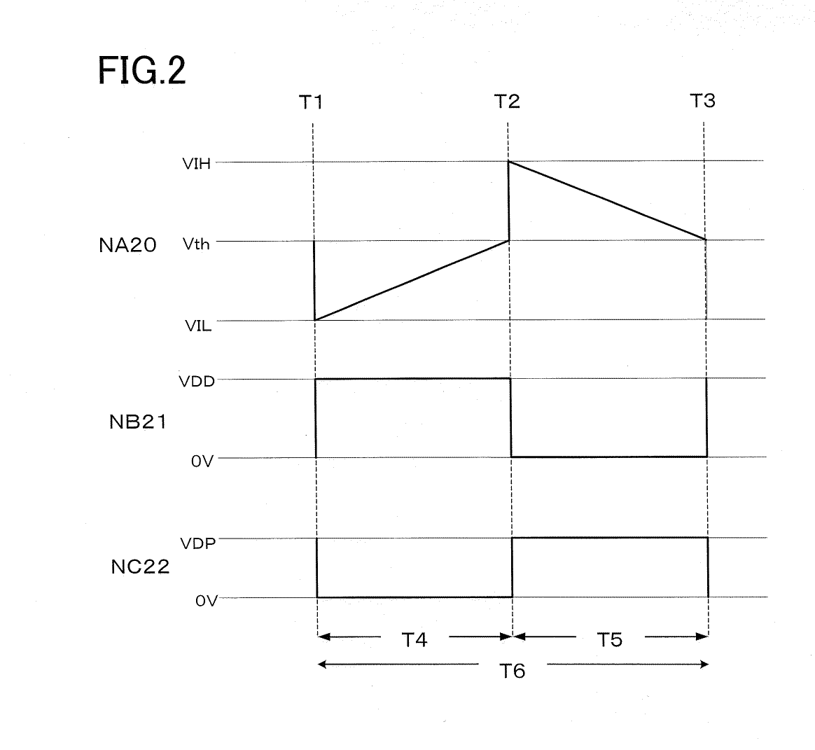

Referring to FIG. 2, the operation of the oscillator circuit of the first embodiment will be described. FIG. 2 is a waveform diagram showing changes in the potential at the nodes NA20, NB21, and NC22 of the oscillator circuit shown in FIG. 1.

Operation at Time T1

Assume that the potential at the node NA20 at time T1 is slightly higher than a threshold voltage Vth of the inverter circuit 7. Thus, the logic level at the node NB21 is “L”. The switch circuit 15 outputs a signal whose potential level is VINV to the second terminal of the capacitance element 10. That is, the potential level at the node NC22 is VINV. The inverter circuit 14 outputs a signal whose logic level is “H”. As a result, the switch circuit 6 allows the flow of the constant current In from the first terminal of each of the capacitance elements 9 and 10 to the low-potential power supply VSS3.

Accordingly, the potential at the node NA20 becomes slightly lower than the threshold voltage Vth. As a result, the inverter circuit 7 outputs a signal whose logic level is “H”. As a result, the logic level at the node NB21 becomes “H”. Next, the switch circuit 15 outputs a signal whose potential level is the potential level of the low-potential power supply VSS3. Next, the potential level at the node NC22 changes from VINV to the potential level of the low-potential power supply VSS3. Next, the potential level at the second terminal of the capacitance element 10 becomes the potential level of the low-potential power supply VSS3. As a result, the potential at the node NA20 is reduced due to capacitive coupling and becomes a potential level VIL.

If charge is maintained before and after a change in the potential at the node NC22, the following relationship between VIL and Vth holds true:

VIL=Vth−C9×VINV/(C9+C10) (1)

In contrast, since the logic level at the node NB21 becomes “H”, the inverter circuit 14 outputs a signal whose logic level is “L”. As a result, the switch circuit 6 allows the flow of the constant current Ip from the high-potential power supply VDD2 to the first terminal of each of the capacitance elements 9 and 10 (that is, the node NA20). A period T4 in which the potential level at the node NA20 changes from VIL to Vth is given by the following equation:

T4=(C9+C10)×(Vth−VIL)/Ip (2)

Equation (1) is substituted for equation (2), thereby yielding equation (3) representing the cycle T4:

T4=C10×VINV/Ip (3)

Operation at Time T2

Assume that the potential at the node NA20 at time T2 is slightly lower than the threshold voltage Vth of the inverter circuit 7. Thus, the logic level at the node NB21 is “H”. The switch circuit 15 outputs a signal whose potential level is the potential level of the low-potential power supply VSS3 (e.g., ground potential) to the second terminal of the capacitance element 10. That is, the potential level at the node NC22 is the potential level of the low-potential power supply VSS3. The inverter circuit 14 outputs a signal whose logic level is “L”. As a result, the switch circuit 6 allows the flow of the constant current Ip from the high-potential power supply VDD2 to the first terminal of each of the capacitance elements 9 and 10.

Accordingly, the potential at the node NA20 becomes slightly higher than the threshold voltage Vth. As a result, the inverter circuit 7 outputs a signal whose logic level is “L”. As a result, the logic level at the node NB21 becomes “L”. Next, the switch circuit 15 outputs a signal whose potential level is the potential level of VINV. Next, the potential level at the node NC22 changes from the potential of the low-potential power supply VSS3 to the potential level of VINV. Next, the potential level at the second terminal of the capacitance element 10 becomes the potential level of VINV. As a result, the potential at the node NA20 is increased due to capacitive coupling and becomes the potential level VIH.

If charge is maintained before and after a change in the potential at the node NC22, the following relationship between VIH and Vth holds true:

VIH=Vth+C9×VINV/(C9+C10) (4)

In contrast, since the logic level at the node NB21 becomes “L”, the inverter circuit 14 outputs a signal whose logic level is “H”. As a result, the switch circuit 6 allows the flow of the constant current In from the first terminal of each of the capacitance elements 9 and 10 (that is, the node NA20) to the low-potential power supply VSS3. A period T5 in which the potential level at the node NA20 changes from VIH to Vth is given by the following equation:

T5=(C9+C10)×(VIH−Vth)/In (5)

Equation (4) is substituted for equation (5), thereby yielding equation (6) representing the cycle T5:

T5=C10×VINV/In (6)

Thus, the cycle (T4+T5) of a clock generated by the oscillator circuit of the first embodiment is given by the following equation:

T6=C10×VINV×(1/In +1/Ip) (7)

If VINV is constant, T6 is the clock cycle having constant period.

### Operation of VINV-Signal Generating Circuit 18 in Oscillator Circuit of First Embodiment

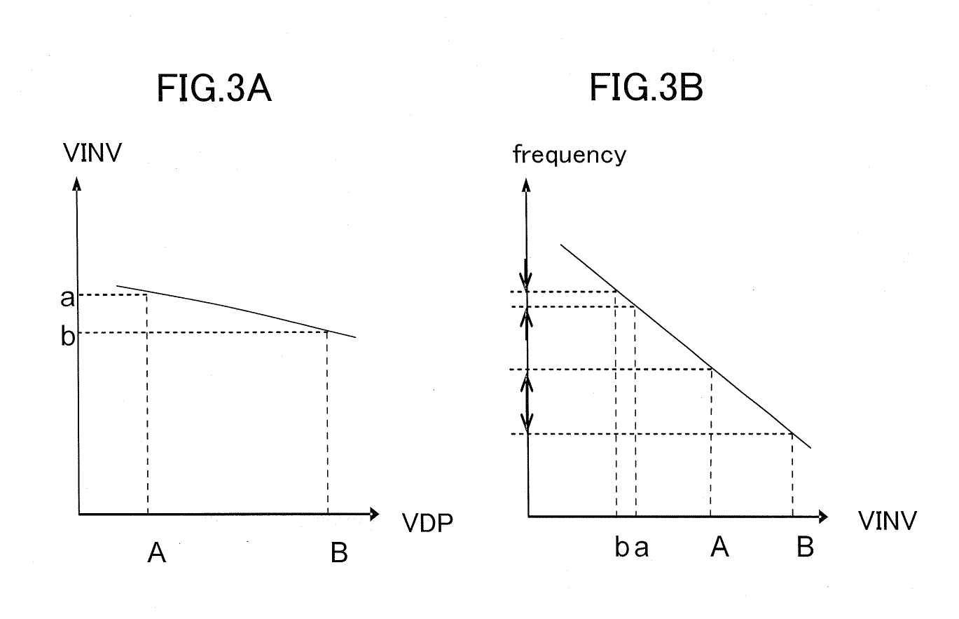

Referring to FIG. 3A, the operation of the VINV-signal generating circuit 18 will be described. FIG. 3A shows a change in the potential level of VINV with respect to a change in the voltage of the high-potential power supply VDP17 in the VINV-signal generating circuit 18.

In FIG. 3A, the voltage (V) of the high-potential power supply VDP17 is plotted in abscissa, and the voltage (V) of the VINV signal 16 is plotted in ordinate.

FIG. 3A shows that the voltage of the VINV signal 16 changes by a small amount from voltage a to voltage b even in the case where the potential of the high-potential power supply VDP17 in the VINV-signal generating circuit 18 changes by a great amount from voltage A to voltage B.

The above changes are due to the following operation of the VINV-signal generating circuit 18. The VINV-signal generating circuit 18 includes the resistor 11 and the NMOS transistor 12, which are connected in series between the high-potential power supply VDP17 and the low-potential power supply VSS3. That is, the VINV-signal generating circuit 18 is a so-called common source circuit. A terminal for outputting the VINV signal 16 is provided at an intermediate node to which the resistor 11 and the drain of the NMOS transistor 12 are connected.

Thus, VINV is determined as follows:

VINV=RMOS12×VDP/(RMOS12+R11) (8)

where RMOS12 is the ON-resistance of the NMOS transistor 12, R11 is the resistance of the resistor 11, and VDP is the potential of the high-potential power supply VDP17.

Accordingly in the VINV-signal generating circuit 18, since RMOS12 is the ON-resistance of the NMOS transistor 12, RMOS12 becomes lower as VDP connected to the gate electrode becomes higher. The ON-resistance of the NMOS transistor is the resistance between source and drain of the NMOS transistor, when the gate voltage is applied to gate of the NMOS transistor.

Therefore, even in the case where VDP is a high potential, since R11 is the constant resistance, VINP is not increased in proportion to the potential VDP as RMOS12 becomes lower. That is, when the resistance RMOS12 becomes smaller, the VINV-signal generating circuit 18 operates so that VINV can be maintained at a substantially constant value regardless of the potential VDP. The high-potential power supply VDP17 in the VINV-signal generating circuit 18 is made different from the high-potential power supply VDD2 of other circuits in order to determine the cycle of the oscillator circuit of the first embodiment regardless of the high-potential power supply VDD2 if the values of VIH and VIL generated at the node NA20 shown in FIG. 2 can be determined by the high-potential power supply VDP17 that is independent of the high-potential power supply VDD2.

Depending on the cycle of the oscillator circuit of the first embodiment, based on the foregoing description, the high-potential power supply VDP17 may be the same as the high-potential power supply VDD2 since VINV can be maintained at a substantially constant value by appropriately selecting the resistance R11 of the resistor 11.

In contrast, in the case where the resistor 11 is made of metal as in a metallic resistor or a resistor made of silicide or the like, the resistor 11 has a positive temperature coefficient with respect to temperature. Also, the ON-resistance of the NMOS transistor 12 has a positive temperature coefficient with respect to temperature. Therefore, since the VINV signal 16 is output from the output terminal connected to the node to which the resistor 11 and the drain of the NMOS transistor 12 are connected, VINV has a potential with a small temperature dependence.

### Advantages of Oscillator Circuit of First Embodiment

Advantages of the oscillator circuit of the first embodiment will be described referring to FIG. 3B. FIG. 3B is a graph showing changes in the frequency of a clock output from the oscillator circuit of the first embodiment in accordance with the potential of the VINV signal 16.

In FIG. 3B, the voltage (V) of the VINV signal 16 is plotted in abscissa, and the frequency (Hz) of the clock output from the oscillator circuit is plotted in ordinate.

FIG. 3B shows that the frequency is in inverse proportion to the voltage of the VINV signal 16. The reason for this is that, as represented by equation (7), the cycle of the clock output from the oscillator circuit is in proportion to the potential of the VINV signal 16. Therefore, the frequency of the clock is in inverse proportion to the potential of the VINV signal 16.

The advantages of the oscillator circuit of the first embodiment are as follows. Referring to FIG. 3A, the potential of the VINV signal 16 output from the VINV-signal generating circuit 18 is maintained at a substantially constant value even in the case where the potential of the high-potential power supply VDP17 greatly changes.

Accordingly, referring to FIG. 3B, in the case where the potential of the VINV signal 16 is substantially constant, the frequency of the clock output from the oscillator circuit of the first embodiment is maintained at a substantially constant value.

This is because, in accordance with the flow of current from the constant-current generating circuit 1, when the potential at the first terminal of the capacitance element increases and reaches the threshold voltage of the inverter circuit, a voltage from a constant voltage source is applied to the second terminal of the capacitance element, and the potential at the first terminal of the capacitance element increases to a predetermined potential. Thereafter, the constant-current generating circuit 1 allows the current to flow out, and the potential at the first terminal of the capacitance element decreases and reaches the threshold voltage of the inverter circuit. Accordingly, a ground voltage from the ground power supply VSS3 is applied to the second terminal of the capacitance element, and the potential at the first terminal of the capacitance element decreases to a predetermined potential.

In the case where the potential of the VINV signal 16 is substantially constant, the predetermined potential reached by the potential at the first terminal of the capacitance element increasing from the threshold voltage of the inverter at time T1 or the predetermined potential reached by the potential at the first terminal of the capacitance element decreasing from the threshold voltage of the inverter at time T2 is substantially constant.

Accordingly, in the case where the current that flows into or out of the first terminal of the capacitance element is the constant current from the constant-current generating circuit 1, the cycle T6 (T4+T5) is constant.

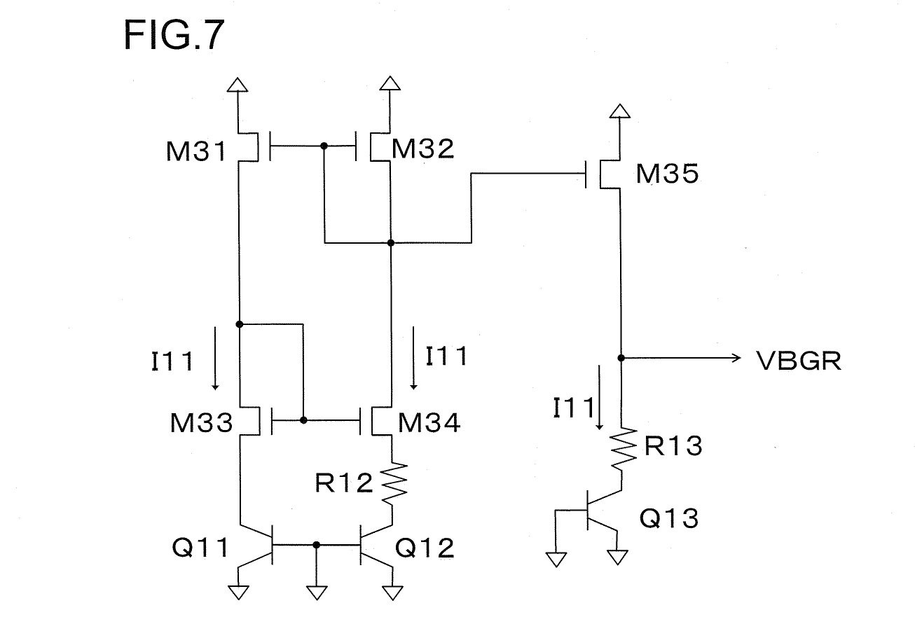

Furthermore, the VINV-signal generating circuit 18 for generating the VINV signal 16 outputs VINV with a substantially constant potential even though the high-potential power supply VDP17 is not a constant voltage source. Therefore, the VINV-signal generating circuit 18 operates in a similar manner as the constant voltage source 35 shown in FIG. 7. However, the VINV-signal generating circuit 18 for generating the VINV signal 16 only includes the resistor 11 and the NMOS transistor 12. Thus, the layout area of the VINV-signal generating circuit 18 is smaller than that of the constant voltage source 35 shown in FIG. 7 since the number of components included in the constant voltage source 35 is greater.

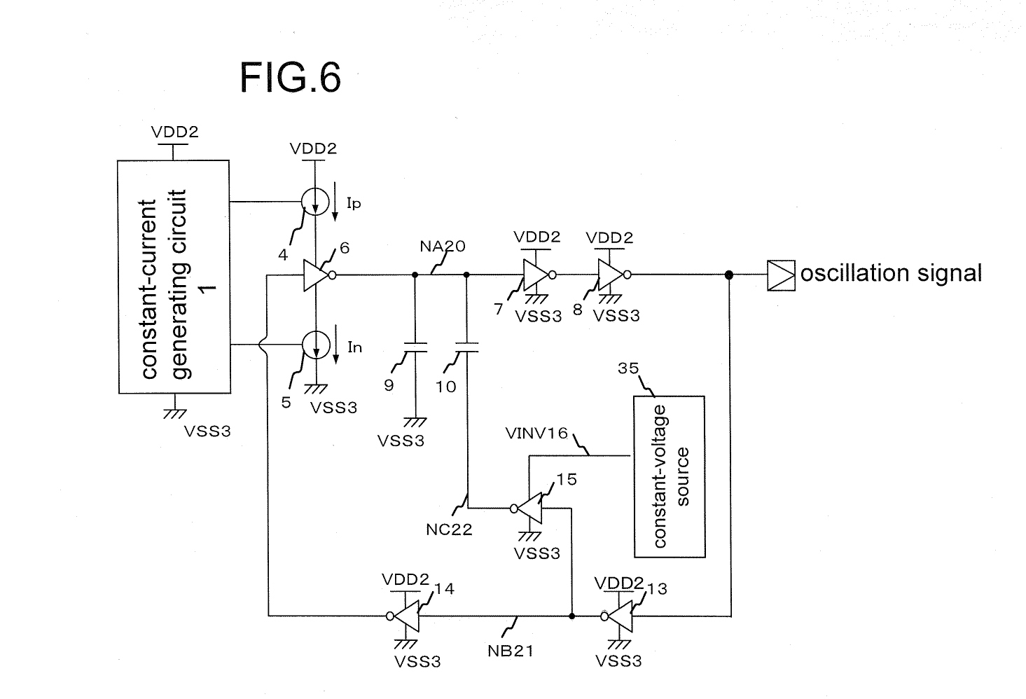

Accordingly, the oscillator circuit of the first embodiment generates a clock whose clock cycle is substantially constant regardless of the power supply voltage and temperature. The layout area of the oscillator circuit of the first embodiment is smaller than that of the oscillator circuit shown in FIG. 6.

### Constant-Current Generating Circuit 1 in Oscillator Circuit of First Embodiment

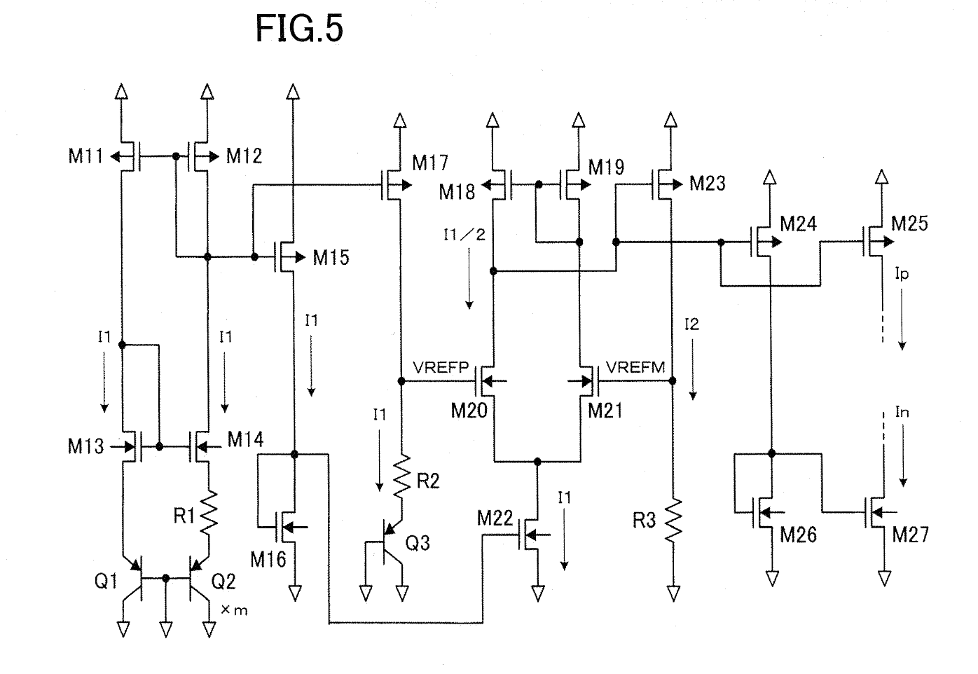

FIG. 5 is a circuit diagram showing the constant-current generating circuit 1. The constant-current generating circuit 1 includes MOS transistors MN1 to M27, bipolar transistors Q1 to Q3, and resistors R1 to R3.

The MOS transistors MN1 and M12 are PMOS transistors. The sources of the MOS transistors MN1 and M12 are connected to the power supply. The gates of the MOS transistors MN1 and M12 are connected to each other and to the drain of the MOS transistor M12. The drain of the MOS transistor MN1 is connected to the drain of the MOS transistor M13. The drain of the MOS transistor M12 is connected to the drain of the transistor M14.

The MOS transistors M13 and M14 are NMOS transistors. The gates of the MOS transistors M13 and M14 are connected to each other and to the drain of the MOS transistor M13. The source of the MOS transistor M13 is connected to the emitter of the bipolar transistor Q1. The source of the MOS transistor M14 is connected to the emitter of the bipolar transistor Q2 via the resistor R1.

The bipolar transistors Q1 and Q2 are PNP bipolar transistors. The bases of the bipolar transistors Q1 and Q2 are connected to each other and to the ground power supply. The collectors of the bipolar transistors Q1 and Q2 are connected to the ground power supply.

The MOS transistors MN1 to M14, the bipolar transistors Q1 and Q2, and the resistor R1 constitute a bias-current generating circuit for generating a bias current. With the bias-current generating circuit, a current I1 flows through the MOS transistors M13 and M14.

The MOS transistor M15 is a PMOS transistor. The MOS transistor M16 is an NMOS transistor. The source of the MOS transistor M15 is connected to the power supply. The gate of the MOS transistor M15 is connected to the drain of the MOS transistor M12. The drain of the MOS transistor M15 is connected to the gate and drain of the MOS transistor M16. The source of the MOS transistor M16 is connected to the ground power supply.

The MOS transistors M15 and M16 constitute a current mirror circuit for generating a bias current using an operational amplifier described later. The current I1, which is the same as the current I1 flowing through the MOS transistors M13 and M14, flows through the MOS transistor M16.

The MOS transistor M17 is a PMOS transistor. The bipolar transistor Q3 is a PNP bipolar transistor. The source of the MOS transistor M17 is connected to the high-potential power supply. The gate of the MOS transistor M17 is connected to the drain of the MOS transistor M12. The drain of the MOS transistor M17 is connected to the emitter of the bipolar transistor Q3 via the resistor R2. The base and collector of the bipolar transistor Q3 are connected to the ground power supply.

The MOS transistor M17, the resistor R2, and the bipolar transistor Q3 constitute a circuit for determining the temperature dependence of a voltage generated using the current I1 of the bias-current generating circuit. A voltage VREFP is generated at the drain of the MOS transistor M17. The temperature dependence of the voltage VREFP is determined by appropriately determining the resistances of the resistors R1 and R2.

The MOS transistors M18 and M19 are PMOS transistors. The sources of the MOS transistors M18 and M19 are connected to the power supply. The gates of the MOS transistors M18 and M19 are connected to each other and to the drain of the MOS transistor M19. The drain of the MOS transistor M18 is connected to the drain of the MOS transistor M20. The drain of the MOS transistor M19 is connected to the drain of the MOS transistor M21.

The MOS transistors M20 and M21 are NMOS transistors. The gate of the MOS transistor M20 is connected to the drain of the MOS transistor M17. The gate of the MOS transistor M21 is connected to the drain of the MOS transistor M23. The sources of the MOS transistors M20 and M21 are connected to each other and to the drain of the MOS transistor M22.

The MOS transistor M22 is an NMOS transistor. The gate of the MOS transistor M22 is connected to the gate and drain of the MOS transistor M16. The source of the MOS transistor M22 is connected to the ground power supply.

The MOS transistor M23 is a PMOS transistor. The source of the MOS transistor M23 is connected to the power supply. The gate of the MOS transistor M23 is connected to the drain of the MOS transistor M18. The drain of the MOS transistor M23 is connected to the gate of the MOS transistor M21 and to the ground power supply via the resistor R3.

The MOS transistors M18 to M23 and the resistor R3 constitute the operational amplifier. Assume that the gate of the MOS transistor M20 is a non-inverting input terminal, the gate of the MOS transistor M21 is an inverting input terminal, and the drain of the MOS transistor M23 is an output terminal. The operational amplifier constitutes a voltage follower. By setting the temperature dependence of the voltage VREFP to be the same as the voltage dependence of the resistor R3, a constant current I2 that does not depend on the power supply voltage and temperature flows through the MOS transistor M23. With the foregoing mirror circuit, the current I1 flows through the MOS transistor M22. Thus, a current I1/2, which is half the current I1, flows through the MOS transistor M20.

The MOS transistors M24 and M25 are PMOS transistors. The MOS transistors M26 and M27 are NMOS transistors. The source of the MOS transistor M24 is connected to the power supply. The gate of the MOS transistor M24 is connected to the drain of the MOS transistor M18. The source of the MOS transistor M25 is connected to the power supply. The gate of the MOS transistor M25 is connected to the drain of the MOS transistor M18. The gate and drain of the MOS transistor M26 are connected to each other and to the drain of the MOS transistor M24. The source of the MOS transistor M26 is connected to the ground power supply. The gate of the MOS transistor M27 is connected to the drain of the MOS transistor M24. The source of the MOS transistor M27 is connected to the ground power supply.

The MOS transistor M25 corresponds to a current source 5a, and the current Ip flows through the MOS transistor M25. The MOS transistor M27 corresponds to a current source 5b, and the current In flows through the MOS transistor M27. The MOS transistors M24 and M26 constitute a current mirror. Thus, the constant current I2, which does not depend on the power supply voltage and temperature, flows as the currents Ip and In through the MOS transistors M25 and M27. The MOS transistor M25 corresponds to the current control circuit 4 shown in FIG. 1, and the MOS transistor M24 corresponds to the current control circuit 5 shown in FIG. 1.

### Second Embodiment

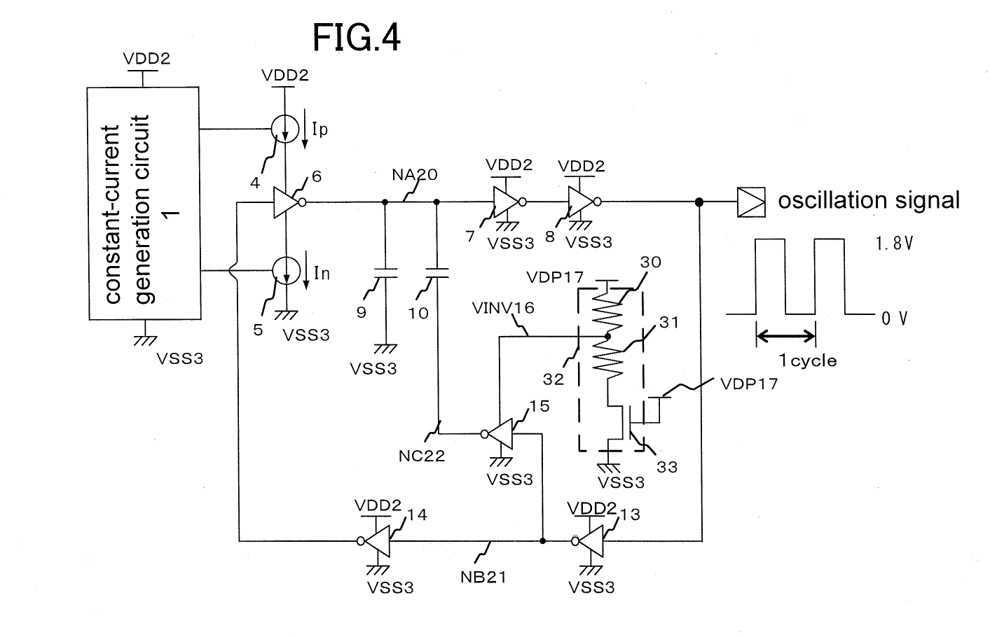

A second embodiment relates to an oscillator circuit that generates a power supply voltage, which is to be connected to a first terminal of a capacitance element that determines an oscillation cycle based on charging and discharging, using a plurality of resistors and the ON-resistance of an MOS transistor. The first and second embodiment differs from each other in that the power supply voltage is generated using a single resistor and the ON-resistance of an MOS transistor in the first embodiment. The second embodiment will be described using FIG. 4.

FIG. 4 is a circuit diagram showing an oscillator circuit according to the second embodiment. FIG. 4 shows the constant-current generating circuit 1, the high-potential power supply VDD2, the low-potential power supply VSS3, the current control circuit 4 for controlling the constant current Ip flowing from the high-potential power supply VDD2, the current control circuit 5 for controlling the constant current In flowing into the low-potential power supply VSS3, the switch circuit 6, the inverter circuit 7, the inverter circuit 8, the capacitance element 9, the capacitance element 10, a resistor 30, a resistor 31, an NMOS transistor 33, the inverter circuit 13, the inverter circuit 14, the switch circuit 15, the VINV signal 16, the high-potential power supply VDP17, a VINV-signal generating circuit 32, the node NA20, the node NB21, and the node NC22. The same components as those shown in FIG. 1 are given the same reference numerals. Therefore, the components other than the resistors 30 and 31, the NMOS transistor 33, and the VINV-signal generating circuit 32 are the same as those described with reference to FIG. 1.

### Structure of Oscillator Circuit of Second Embodiment

The oscillator circuit of the second embodiment is different from that of the first embodiment in that the VINV-signal generating circuit 18 is replaced with the VINV-signal generating circuit 32. The remaining components are the same as those of the first embodiment.

The VINV-signal generating circuit 32 includes the resistor 30, the resistor 31, and the NMOS transistor 33. The resistor 30 is connected to the high-potential power supply VDP17 and a first terminal of the resistor 31. A second terminal of the resistor 31 is connected to the drain of the NMOS transistor 33. The gate electrode of the NMOS transistor 33 is connected to the high-potential power supply VDP17. The source of the NMOS transistor 33 is connected to the low-potential power supply VSS3. An output terminal for outputting the VINV signal 16 is connected to an intermediate node to which the resistor 30 and the resistor 31 are connected.

### Operation of VINV-Signal Generating Circuit 32 in Oscillator Circuit of Second Embodiment

Since the VINV-signal generating circuit 32 has the foregoing structure, the potential of the VINV signal 16 of the second embodiment will be as follows:

VINV=(RMOS33+R31)×VDP/(RMOS33+R30+R31) (9)

where RMOS33 is the ON-resistance of the NMOS transistor 33, VDP is the potential of the high-potential power supply VDP17, R30 is the resistance of the resistor 30, and R31 is the resistance of the resistor 31.

Accordingly in the VINV-signal generating circuit 32, since RMOS33 is the ON-resistance of the NMOS transistor 33, RMOS33 becomes lower as VDP connected to the gate electrode becomes higher. Note that the amount of reduction in the ON-resistance of the NMOS transistor 33 of the second embodiment in accordance with an increase in VDP is greater than the amount of reduction in the ON-resistance of the NMOS transistor 12 of the first embodiment.

Therefore, since R30 and R31 are constant resistances, even in the case where VDP is a high potential, VINP is not increased in proportion to the potential VDP as RMOS33 becomes lower. That is, when the resistance RMOS33 becomes smaller, the VINV-signal generating circuit 32 operates so that VINV can be maintained at a substantially constant value. Even though the ON-resistance of the NMOS transistor 33 of the second embodiment becomes suddenly smaller, a sudden reduction in the potential VINV can be suppressed due to the presence of R31.

### Operation of Oscillator Circuit of Second Embodiment

When the oscillator circuit of the second embodiment is compared with that of the first embodiment, the difference resides in the VINV-signal generating circuit 32. However, the oscillator circuit of the second embodiment operates in a similar manner since the cycle of a clock output from the oscillator circuit is determined based on charging and discharging of C10. Thus, the cycle of a clock output from the oscillator circuit of the second embodiment is given by equation (7).

### Advantages of Oscillator Circuit of Second Embodiment

The oscillator circuit of the second embodiment has the following advantages. Referring to FIG. 3A, the potential of the VINV signal 16 output from the NMOS transistor 33 is maintained at a substantially constant value even in the case where the potential of the high-potential power supply VDP17 greatly changes.

Accordingly, referring to FIG. 3B, in the case where the potential of the VINV signal 16 is substantially constant, the frequency of the clock output from the oscillator circuit of the second embodiment is maintained at a substantially constant value.

Therefore, the oscillator circuit of the second embodiment has an advantage that the frequency of the clock output from the oscillator circuit is maintained at a constant value.

Furthermore, the VINV-signal generating circuit 32 for generating the VINV signal 16 can be configured only using the resistor 30, the resistor 31, and the NMOS transistor 33. The high-potential power supply VDP17 need not be a constant voltage source. Thus, the layout area of the VINV-signal generating circuit 32 can be reduced. As a result, since the layout area of the VINV-signal generating circuit 32 is smaller than that of the constant voltage source 35 shown in FIG. 7, the layout area of the oscillator circuit of the second embodiment can be greatly reduced.

When a constant voltage source is used to make the potential of the VINV signal 16 stable, a large number of circuit elements are necessary to configure the constant voltage source. Thus, the layout area of the entire oscillator circuit is increased.

Since the VINV signal 16 is output from the output terminal connected to the node to which the resistor 30 and the resistor 31 are connected, all the NMOS transistor 33 and the resistors 30 and 31 have positive temperature coefficients. Therefore, VINV has a potential with a small temperature dependence.

Accordingly, the oscillator circuit of the second embodiment generates a clock with a substantially constant clock frequency regardless of the power supply voltage and temperature. The layout area of the oscillator circuit of the second embodiment is smaller than that shown in FIG. 6.

According to the embodiments, the number of elements constituting a voltage source that determines the cycle of a clock generated by an oscillator circuit can be reduced. Thus, the oscillator circuit occupying a small layout area can be provided.

What is claimed is:

1. An oscillator circuit comprising:
a capacitance element;
an inverter for inverting a voltage at a first terminal of the capacitance element and outputting the inverted voltage;
a voltage source including a resistor and an NMOS transistor that are connected in series between a first high-potential power supply and a ground power supply, the voltage source outputting a voltage from a node to which the resistor and the NMOS transistor are connected;
a switch circuit for connecting a second terminal of the capacitance element to one of the voltage source and the ground power supply in accordance with the voltage output from the inverter; and
a constant-current source for allowing flow of a constant current into the first terminal of the capacitance element or flow of a constant current out of the first terminal of the capacitance element in accordance with the voltage output from the inverter, the constant-current source being connected to a second high-potential power supply.

2. The oscillator circuit according to claim 1, wherein the first high-potential power supply and the second high-potential power supply are the same high-potential power supply.

3. The oscillator circuit according to claim 1, wherein the constant-current source allows the flow of the current out of the capacitance element in a case where the second terminal of the capacitance element is connected to the voltage source and allows the flow of the current into the capacitance element in a case where the second terminal of the capacitance element is connected to the ground power supply.

4. An oscillator circuit comprising:
a capacitance element;
an inverter for inverting a voltage at a first terminal of the capacitance element and outputting the inverted voltage;
a voltage source including a first resistor, a second resistor, and an NMOS transistor that are connected in series between a first high-potential power supply and a ground power supply, the voltage source outputting a voltage from a node to which the first resistor and the second resistor are connected;
a switch circuit for connecting a second terminal of the capacitance element to one of the voltage source and the ground power supply in accordance with the voltage output from the inverter; and
a constant-current source for allowing flow of a constant current into the first terminal of the capacitance element or flow of a constant current out of the first terminal of the capacitance element in accordance with the voltage output from the inverter, the constant-current source being connected to a second high-potential power supply.

5. The oscillator circuit according to claim 4, wherein the first high-potential power supply and the second high-potential power supply are the same high-potential power supply.

6. The oscillator circuit according to claim 4, wherein the constant-current source allows the flow of the current out of the capacitance element in a case where the second terminal of the capacitance element is connected to the voltage source and allows the flow of the current into the capacitance element in a case where the second terminal of the capacitance element is connected to the ground power supply.

7. A semiconductor device comprising:
a capacitance element;
an inverter for inverting a voltage at a first terminal of the capacitance element and outputting the inverted voltage;
a voltage source including a resistor and an NMOS transistor that are connected in series between a first high-potential power supply and a ground power supply, the voltage source outputting a voltage from a node to which the resistor and the NMOS transistor are connected;
a switch circuit for connecting a second terminal of the capacitance element to one of the voltage source and the ground power supply in accordance with the voltage output from the inverter; and
a constant-current source for allowing flow of a constant current into the first terminal of the capacitance element or flow of a constant current out of the first terminal of the capacitance element in accordance with the voltage output from the inverter, the constant-current source being connected to a second high-potential power supply.

8. The semiconductor device according to claim 7, wherein the first high-potential power supply and the second high-potential power supply are the same high-potential power supply.

9. The semiconductor device according to claim 7, wherein the constant-current source allows the flow of the current out of the capacitance element in a case where the second terminal of the capacitance element is connected to the voltage source and allows the flow of the current into the capacitance element in a case where the second terminal of the capacitance element is connected to the ground power supply.
